(19) United States
(12) Patent Application Publication
(10) Pub. No.: US 2026/0206479 A1
(43) Pub. Date: Jul. 16, 2026

(54) FILM, PREPARATION METHOD THEREOF AND PHOTOELECTRIC DEVICE

(71) Applicants: Guangdong Juhua Research Institute of Advanced Display, Guangzhou, Guangdong (CN); TCL Technology Group Corporation, Huizhou, Guangdong (CN)

(72) Inventor: Huamin WANG, Guangzhou, Guangdong (CN)

(73) Assignees: Guangdong Juhua Research Institute of Advanced Display, Guangzhou, Guangdong (CN); TCL Technology Group Corporation, Huizhou, Guangdong (CN)

(21) Appl. No.: 19/132,360

(22) PCT Filed: Sep. 27, 2023
(86) PCT No.: PCT/CN2023/122241

§ 371 Date: May 22, 2025

(30) Foreign Application Priority Data
Nov. 25, 2022 (CN) 202211491232.2

(51) Int. Cl. H10K 85/10; B82Y 20/00; B82Y 40/00; C08F 126/06; C08K 9/04; C09D 5/22; C09D 5/24; C09D 7/20; C09D 7/40; C09D 7/62; C09D 139/04; C09K 11/02; C09K 11/88; C09K 113/00; H10K 50/115; H10K 71/12; H10K 71/40; H10K 101/30

(52) U.S. Cl. CPC H10K 85/141; C08F 126/06; C09D 5/22; C09D 5/24; C09D 7/20; C09D 7/62; C09D 7/67; C09D 139/04; C09K 11/02; C09K 11/883; H10K 50/115; H10K 71/12; H10K 71/40; H10K 85/151; B82Y 20/00; B82Y 40/00; C08F 2800/10; C08F 2810/20; C08K 9/04; C08K 2201/011; C09K 2113/00; H10K 2101/30

(57) ABSTRACT

A film, a preparation method thereof and a photoelectric device are disclosed. The film includes a cross-linked system with voids and a nanoparticle filled in the voids. Compared with a cross-linked system without ions, the cross-linked system of the present disclosure contains cations and anions, so that the cross-linked system itself has good conductivity, which is conducive to the recombination of electrons and holes in the film, thereby making the film have good luminescent performance.

The present disclosure claims priority to Chinese Present disclosure NO. 202211491232.2 filed in the China National Intellectual Property Administration on Nov. 15, 2022 and entitled “FILM, PREPARATION METHOD THEREOF, PHOTOELECTRIC DEVICE AND DISPLAY DEVICE”, the content of which is incorporated herein by reference in its entirety.

### TECHNICAL FIELD

The present disclosure relates to a field of display technologies, and more particularly, to film, preparation method thereof and photoelectric device.

### BACKGROUND

The luminous film for the flexible photoelectric device needs to have good luminous performance, bending resistance and stress fatigue resistance. The cross-linked substance could be incorporated into the luminous film to enhance the bending resistance due to the good bending resistance. However, after the cross-linked substance is incorporated into the luminous film, the conductivity of the luminous film is affected due to the poor conductivity of the cross-linked substance, and the recombination of electrons and holes in the film is affected, thereby affecting the luminous performance of the film.

### Technical Solution

In view of this, the present disclosure provides a film, a preparation method thereof and a photoelectric device.

The present disclosure provides a film. The film includes a cross-linked system having voids and a nanoparticle filled in the voids.

The cross-linked system includes a cross-linking material having a general structure as shown in formula I:

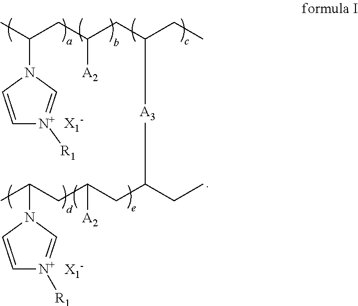

R₁ is selected from an alkyl group having 1-6 carbon atoms.

A₂ is independently selected from any one of

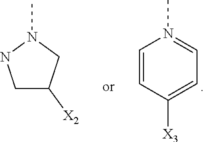

A₃ is selected from any one of

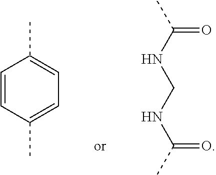

X₁, X₂, X₃ are independently selected from any one of Cl, Br, or I.

a, c, d are each independently selected from any one of integers from of 2-50, b and e are each independently selected from any one of integers from 0-50.

Alternatively, the film is composed of the cross-linked system having voids and the nanoparticle filled in the voids.

A current passing through the film under a voltage of 6 V is 4.9-5.6 mA.

A transparency of the film is 87%-92%.

A LUMO energy level of the film is 3.5-3.6 eV.

A HOMO energy level of the film is 6.0-6.2 eV.

Alternatively, a mass ratio of the cross-linked system to the nanoparticle in the film is 1:(10-100).

An average particle size of the nanoparticle is 15-40 nm.

A thickness of the film is 30-40 nm.

Alternatively, the cross-linked system includes one or more of the following cross-linking compounds having the following general structures:

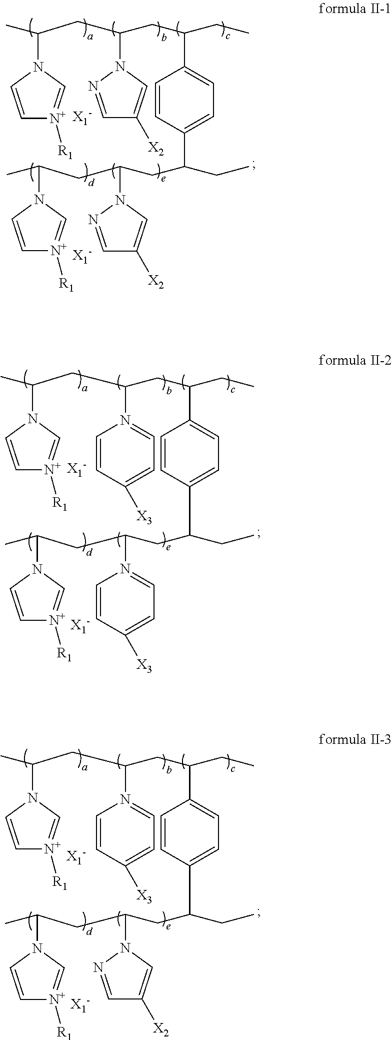

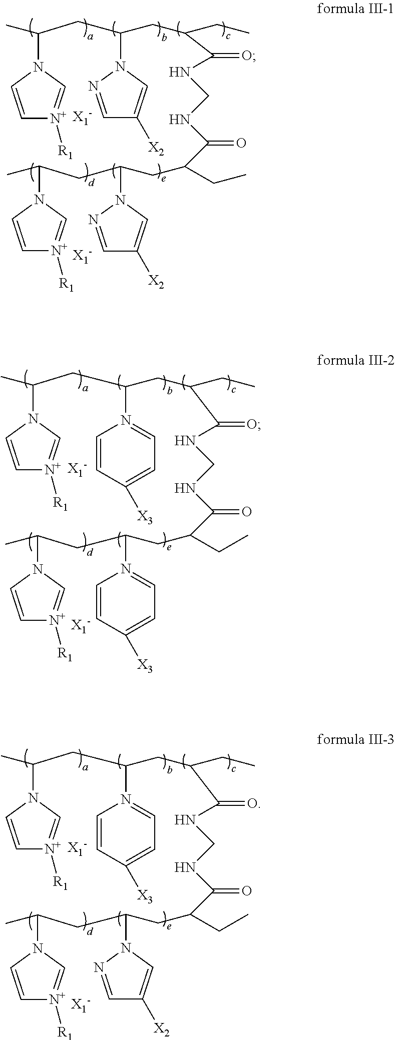

b and e are independently selected from any one of integers from 1-50.

Alternatively, the nanoparticle includes quantum dot, and the quantum dot is selected from one or more of a single-structure quantum dot, a core-shell quantum dot, and a perovskite semiconductor material.

Alternatively, a material of the single-structure quantum dot, a core material of the core-shell quantum dot, and a shell material of the core-shell quantum dot are respectively selected from a group II-VI compound, a group IV-VI compound, a group III-V compound, and a group I-III-VI compound.

The group II-VI compound is selected from CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe.

The group IV-VI compound is selected from SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe.

The group III-V compound is selected from GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb.

The group I-III-VI compound is selected from CuInS₂, CuInSe₂ and AgInS₂.

The perovskite semiconductor material is selected from a doped or undoped inorganic perovskite semiconductor, or an organic-inorganic hybrid perovskite semiconductor.

The inorganic perovskite semiconductor has a general structure formula of AMX₃, wherein A is a Cs⁺ ion, M is a divalent metal cation selected from at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halide anion selected from at least one of Cl⁻, Br⁻ and I⁻.

The organic-inorganic hybrid perovskite semiconductor has a general structure formula of BMX₃, wherein B is an organic amine cation selected from CH₃(CH₂)ₙ₋₂NH³⁺ or [NH₃(CH₂)ₙNH₃]²⁺ (wherein n≥2), M is a divalent metal cation selected from at least one of Pb²⁺, Sn², Cu²⁺, Ni²⁺, Cd²⁺, Cr²⁺, Mn²⁺, Co²⁺, Fe²⁺, Ge²⁺, Yb²⁺ and Eu²⁺, and X is a halide anion selected from at least one of Cl⁻, Br⁻ and I⁻.

A preparation method of a film, including:
providing a mixed solution and a dispersion liquid, the mixed solution includes heterocyclic compound containing unsaturated substituent, ionic compound, and cross-linking agent, and the dispersion liquid includes nanoparticle; mixing the mixed solution with the dispersion liquid to obtain a film-forming solution; and
providing a substrate, setting the film-forming solution on the substrate, and heating to start a crosslinking reaction to obtain the film.

Alternatively, the heterocyclic compound is selected from at least one of pyrazole and pyridine.

The unsaturated substituent is selected from vinyl or propenyl.

The ionic compound contains an imidazole cation and a halide anion.

The cross-linking agent is selected from at least one of divinylbenzene and N,N′-methylenebisacrylamide.

Alternatively, a temperature of the heating is 75-90° C.

A time of the heating is 10-20 min.

Alternatively, a molar ratio of the heterocyclic compound containing unsaturated substituent, the ionic compound and the cross-linking agent is (0-3):(2-3):(1-2).

A concentration of the heterocyclic compound containing unsaturated substituent is 0-0.3 mol/L.

A concentration of the ionic compound is 0.2-0.3 mol/L.

A concentration of the cross-linking agent is 0.1-0.2 mol/L.

Alternatively, the molar ratio of the heterocyclic compound containing unsaturated substituent, the ionic compound and the cross-linking agent is (2-3):(2-3):(1-2).

A concentration of the heterocyclic compound containing unsaturated substituent is 0.2-0.3 mol/L.

Alternatively, the heterocyclic compound containing an unsaturated substituent is selected from at least one of 4-halogen-1-vinylpyrazole and 4-halogen-1-vinylpyridine.

The ionic compound is a 1-vinyl-3-alkyl imidazole halide salt.

Alternatively, the 4-halogen-1-vinylpyridine is selected from at least one of 4-chloro-1-vinylpyridine and 4-bromo-1-vinylpyridine.

The 4-halogen-1-vinylpyrazole is selected from at least one of 4-chloro-1-vinylpyrazole and 4-bromo-1-vinylpyrazole.

The 1-vinyl-3-alkyl imidazole halide salt is selected from at least one of 1-vinyl-3-ethyl imidazole chloride, 1-vinyl-3-ethyl imidazole bromide, 1-vinyl-3-propyl imidazole chloride, 1-vinyl-3-propyl imidazole bromide, 1-vinyl-3-butyl imidazole chloride, and 1-vinyl-3-butyl imidazole bromide.

Alternatively, the mixed solution is prepared by the following method: the heterocyclic compound containing unsaturated substituent is dispersed in a solvent, then the ionic compound is added and mixed, and finally the crosslinking agent is added and mixed to obtain the mixed solution.

Alternatively, the solvent is selected from at least one of ethanol, methanol, propanol and n-octane.

A photoelectric device, includes an anode, a cathode, and an emission material layer, located between the anode and the cathode, wherein the emission material layer includes the film above-mentioned.

Alternatively, a material of the metal electrode is selected from at least one of Al, Ag, Cu, Mo, Au, Ba, Ca and Mg; a material of the carbon electrode is selected from at least one of graphite, carbon nanotube, graphene and carbon fiber; a material of the doped or undoped metal oxide electrode is selected from at least one of ITO, FTO, ATO, AZO, GZO, IZO, MZO and AMO; and a material of the composite electrode is selected from at least one of AZO/Ag/AZO, AZO/Al/AZO, ITO/Ag/ITO, ITO/Al/ITO, ZnO/Ag/ZnO, ZnO/AI/ZnO, TiO₂/Ag/TiO₂, TiO₂/Al/TiO₂, ZnS/Ag/ZnS and ZnS/Al/ZnS.

Alternatively, the photoelectric device further including: a hole functional layer between the anode and the emission material layer.

The photoelectric device further including: an electron functional layer between the emission material layer and the cathode.

Alternatively, the hole functional layer includes one or more of a hole injection layer and a hole transport layer; when the hole functional layer includes both the hole injection layer and the hole transport layer, the hole injection layer is arranged on the side close to the anode, and the hole transport layer is arranged on the side close to the emission material layer.

The electron functional layer includes one or more of an electron injection layer and an electron transport layer; when the electron functional layer includes both the electron injection layer and the electron transport layer, the electron injection layer is arranged on the side of the cathode, and the electron transport layer is arranged on the side of the emission material layer.

Alternatively, a material of the hole injection layer is selected from one or more of PEDOT:PSS, F4-TCNQ, HATCN, CuPc, MCC, transition metal oxide, transition metal chalcogenide; wherein the transition metal oxide includes one or more of NiO, MoO₂, WO₃, CuO; the transition metal chalcogenide includes one or more of MoS₂, MoSe₂, WS₃, WSe₃, CuS.

A material of the hole transport layer is selected from one or more of TFB, PVK, poly-TPD, PFB, TCATA, CBP, TPD, NPB, PEDOT:PSS, TPH, TAPC, Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, CuSCN.

A material of the electron transport layer includes one or more of inorganic nanocrystalline material, doped inorganic nanocrystalline material, and organic material; the inorganic nanocrystalline material includes one or more of zinc oxide, titanium dioxide, tin dioxide, aluminum oxide, calcium oxide, silicon dioxide, gallium oxide, zirconium oxide, nickel oxide, and zirconia; the doped inorganic nanocrystalline material is inorganic nanocrystalline material containing a doping element, and the doping element is selected from one or more of Mg, Ca, Li, Ga, Al, Co, and Mn; and the organic material includes one or both of polymethyl methacrylate and polyvinyl butyral.

A material of the electron injection layer includes at least one of LiF/Yb, RbBr, ZnO, Ga₂O₃, Cs₂CO₃, and Rb₂CO₃.

The film provided by the present disclosure includes a cross-linked system with voids and a nanoparticle filled in the voids. Compared with a cross-linked system without ions, the cross-linked system of the present disclosure contains cations and anions, so that the cross-linked system itself has good conductivity, which is conducive to the recombination of electrons and holes in the film, thereby making the film have good luminescent performance.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings could be obtained based on these drawings.

FIG. 1 is a flowchart of a method for preparing a film according to an embodiment of the present disclosure.

FIG. 2 is a schematic diagram of the structure of a photoelectric device according to an embodiment of the present disclosure.

FIG. 3 is a schematic diagram of the structure of a photoelectric device according to another embodiment of the present disclosure.

In which, the reference numeral indicates:

anode 1, emission material layer 2, cathode 3, hole injection layer 4, hole transport layer 5, hole functional layer 6, electron injection layer 7, electron transport layer 8, electron functional layer 9, photoelectric device 10.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The following are described in detail. It should be noted that the description order of the following embodiments is not taken as a limitation to the preferred order of the embodiments. In addition, in the description of the present disclosure, the term “comprising/including” means “comprising/including but not limited to”. The terms “first, second, third, etc”. are only used as signs and do not impose numerical requirements or establish order.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

Additionally, in the description of the present disclosure, various embodiments of the present application can exist in a range format; it should be understood that the description in a range format is merely used for convenience and brevity, and should not be used as a limitation on the scope of the present application; therefore, it should be considered that the description of the range has specifically disclosed all possible sub-ranges and individual numerical values within the range. For example, it should be considered that the description of a range from 0.04 to 0.1 has specifically disclosed sub-ranges, such as from 0.04 to 0.05, from 0.05 to 0.06, from 0.06 to 0.07, from 0.07 to 0.09, etc., and individual numbers within the range, such as 0.04, 0.05, and 0.06, regardless of the range. In addition, whenever a numerical range is indicated herein, it is meant to include any cited numeral (fractional or integral) within the indicated range.

The first aspect, the present disclosure provides a film. The film includes a cross-linked system having voids, and a nanoparticle filled in the voids.

In some embodiments, the cross-linked system includes a cross-linking material having a general structure as shown in formula I. The cross-linked system, in addition to having cross-linking properties, also contains anions and cations, and has good electrical conductivity.

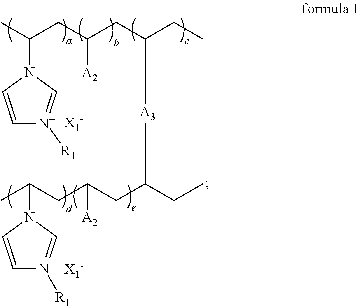

Wherein R₁ is selected from an alkyl group having 1-6 carbon atoms. In some embodiments, the number of the carbon atoms could also be 2, 3, 4, or 5. The alkyl group could be a straight chain alkyl group or a branched chain alkyl group, but not a cyclic alkyl group. The cyclic alkyl group could affect the cross-linking process and the cross-linking degree, and thus affect the flexibility and deformation resistance of the final cross-linked ionic liquid additive. The number of the carbon atoms could not be too high, because too high (e.g., greater than 7) could affect the cross-linking process and the cross-linking degree, and also affect the flexibility and deformation resistance of the final cross-linked ionic liquid additive. The cross-linking degree of the cross-linked ionic liquid additive needs to be within a suitable range to have good bending resistance.

A₂ is independently selected from any one of

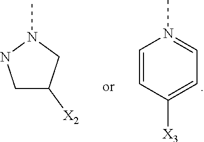

A₂ is connected to the main chain of formula I by a dotted line.

A₃ is selected from any one of

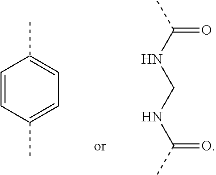

A₃ is connected to the main chain of formula I by a dotted line.

X₁, X₂, X₃ are independently selected from any one of Cl, Br, or I. X₁⁻ represents any one of Cl⁻, Br⁻, or I⁻.

The polymerization degree a, c, d are each independently selected from any one of integers from of 2-50. Each independently means that the values of a, c, d do not affect each other, and specific values of a, c, d depend on the degree of cross-linking reaction. In some embodiments, a, c, d could each independently be selected from 3, 4, 5, 6, 8, 10, 12, 15, 17, 19, 20, 22, 23, 25, 30, 33, 36, 40, 41, 43, 45, 47, 49, etc., but are not limited to the above values. A₃ is a group corresponding to a cross-linking agent, so its polymerization degree c. is not 0.

The polymerization degrees b and e are each independently selected from any one of integers from 0-50. The specific values of b and e also depend on the degree of the cross-linking reaction. In some embodiments, b and e could be each independently selected from 1, 2, 3, 4, 5, 6, 8, 10, 12, 15, 17, 19, 20, 22, 23, 25, 30, 33, 36, 40, 41, 43, 45, 47, 49, etc., but are not limited to the above values. When the polymerization degree of A₂ is 0, A₂ does not exist in the formula I,

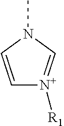

is connected to A₃. Compared with the cross-linking degree, the present disclosure pays more attention to the flexibility, bending resistance or stress fatigue resistance of the film, as long as the above properties of the film are within a suitable range.

In some embodiments, the film is composed of the cross-linked system having voids and the nanoparticle filled in the voids.

In some embodiments, a composite material used to make the film includes the nanoparticle and a cross-linking material. The cross-linking material could also be referred to as a cross-linked ionic liquid. The nanoparticle could include quantum dot luminous material, etc. The composite material could be used to make the above film, which could also be referred to as a quantum dot luminous film.

In some embodiments, the cation includes an imidazole cation. The anion includes a halogen anion. The cation and the anion are capable of freely moving in the cross-linked system, which is conducive to the recombination of electrons and holes in the film. Therefore, compared with a cross-linked system or a film that does not contain freely moving ions, the film of the present disclosure has good electrical conductivity and bending resistance, and could be used in flexible photoelectric device.

In some embodiments, the film of the present disclosure has good electrical conductivity, and a current passing through the film under a voltage of 6 V is 4.9-5.6 mA.

In addition, the film provided by the present disclosure also has good transparency. The cross-linked system in the film has voids, and the nanoparticle is filled in the voids, so that the voids physically limit the nanoparticle, preventing the nanoparticle from moving disorderly in the cross-linked system. The cross-linked system has good transparency, which could ensure that the light emitted by the nanoparticle is not greatly attenuated and does not occur in a large direction, thereby effectively ensuring the luminous performance of the film.

In addition, a LUMO energy level of the film of the present disclosure is 3.5-3.6 eV, and a HOMO energy level is 6.0-6.2 eV, so that the film has good photoelectric performance and could be used as an emission material layer of a photoelectric device.

In some embodiments, the cross-linked system of the film of the present disclosure could form an integral stress structure with the nanoparticle wrapped therein, so that the film has good bending resistance in addition to good photoelectric performance, and the film could be used as an emission material layer of a flexible photoelectric device. The flexible photoelectric device includes, but is not limited to, a flexible QLED (Quantum-Dot Luminous Diode) photoelectric device, etc.

In some embodiments, a mass ratio of the cross-linked system to the nanoparticle in the film could be 1:(10-100). In other embodiments, a mass ratio of the cross-linked system to the nanoparticle could also be 1:(11-99), 1:(15-95), 1:(20-90), 1:(25-85), 1:(30-80), 1:(35-75), 1:(40-70), 1:(45-65), 1:(50-60), etc., but is not limited to the above numerical ranges. If the mass of the cross-linked system in the film is too low, the cross-linking degree is insufficient, the flexibility and the bending resistance of the final film are poor, the film is brittle, and the film is easily broken and creased during repeated bending, thereby affecting the display performance. If the mass of the cross-linked system in the film is too high, the flexibility of the film is too strong, the bending force is large, and in addition, the cross-linking degree that is too high also affects the luminous path of the nanoparticle, thereby reducing the display effect of the film.

In some embodiments, an average particle size of the nanoparticle is 15-40 nm, and could also be 15-19 nm, 20-25 nm, 26-30 nm, 31-35 nm, 36-39 nm, etc., or a range formed by any two of the above values.

In some embodiments, a thickness of the film is 30-40 nm. In some embodiments, the thickness of the film could be 31 nm, 32 nm, 33 nm, 34 nm, 35 nm, 36 nm, 37 nm, 38 nm, 39 nm, or a range formed by any two of the above values. If the thickness of the film is too thin, the luminous brightness is insufficient, the luminous efficiency is not high, the display performance is affected, and the film is easily broken during repeated bending. If the thickness of the film is too thick, the luminous uniformity is poor, and the bending resistance is too strong, which is also not conducive to repeated bending. In other embodiments, if the film includes more than two sublayers, for example, two sublayers, three sublayers, etc. The total thickness of the film formed by multiple sublayers is preferably in the range of 30 nm to 40 nm.

In some embodiments, the film could be composed of the nanoparticle and the cross-linked system. However, the film could also include other additives, for example, dicumyl peroxide and other co-cross-linking agents, as long as the added other additives do not affect the occurrence of the cross-linking reaction and the formation of the cross-linked system, and do not affect the luminous characteristics of the nanoparticle.

In the film mentioned above, the voids in the cross-linked system could wrap and physically limit the nanoparticle, preventing the movement of the nanoparticle, so that the entire film forms an overall stress system, has good flexibility and deformation resistance, and could prevent damage to the internal structure of the film and cracking of the film layer during repeated bending.

In some embodiments, the film could further include an organic luminous material. The organic luminous material could be selected from one or more of a diaryl anthracene derivative, a stilbene aromatic derivative, a pyrene derivative or a fluorene derivative, a blue luminous TBPe fluorescent material, a green luminous TTPA fluorescent material, an orange luminous TBRb fluorescent material, and a red luminous DBP fluorescent material.

In some embodiments, the cross-linked system could be formed by cross-linking polymerization of heterocyclic compound containing unsaturated substituent, ionic compound, and cross-linking agent, or by cross-linking polymerization of ionic compound and cross-linking agent. The heterocyclic compound containing unsaturated substituent could include any one or both of 4-halo-1-vinylpyrazole and 4-halo-1-vinylpyridine. The ionic compound could is a 1-vinyl-3-alkyl imidazole halide salt. The halide refers to the carbon atom being substituted by a halogen, such as Cl, Br, and I.

In the above embodiments, the cross-linked system in the film and the nanoparticle in the voids thereof could form an integral stress structure, and the film has good flexibility and bending resistance. Meanwhile, the cross-linked system contains a large number of cations and anions, and thus has high conductivity, so that the film could be used as an emission material layer of a flexible photoelectric device.

In some embodiments, the cross-linked system includes one or more of the following cross-linking compounds having the following general structures:

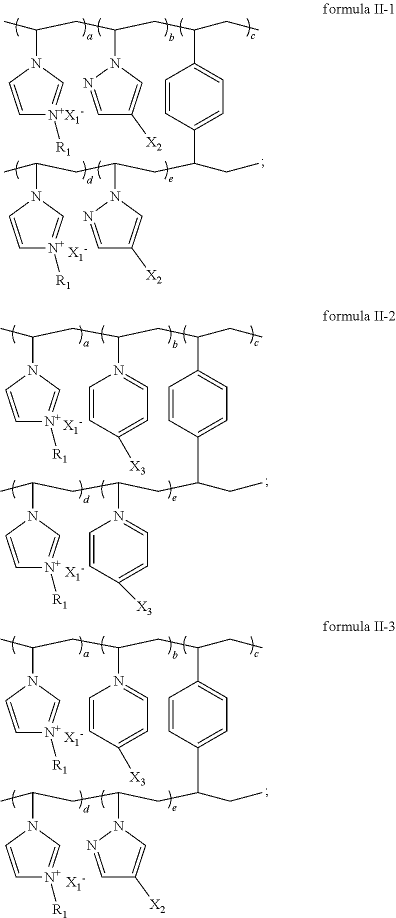

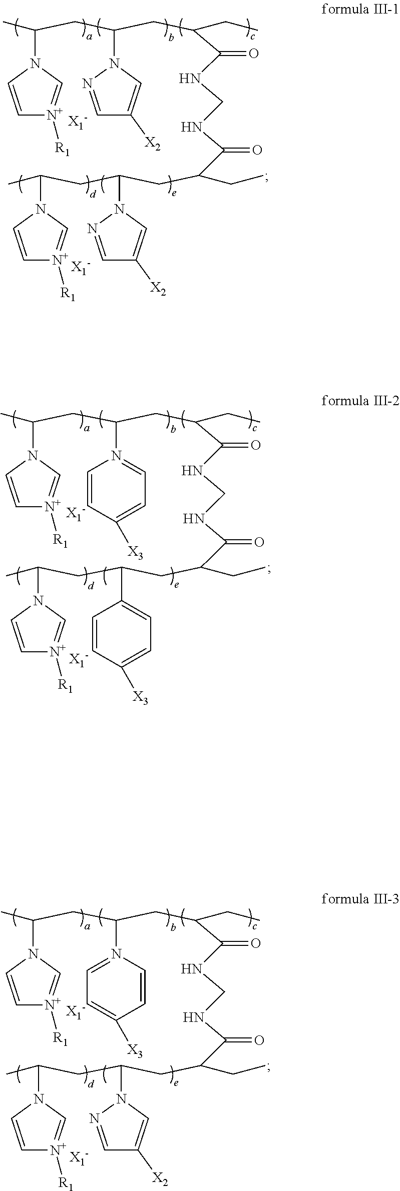

b and e are independently selected from any one of integers from 1-50.

Alternatively, in the embodiments of the present disclosure, the nanoparticle includes quantum dot. The quantum dot is selected from, but not limited to, one or more of a single-structure quantum dot, a core-shell quantum dot, and a perovskite semiconductor material. A ligand of the quantum dot is selected from one or more of oleylamine, oleic acid, 1-octadecene, etc.

A material of the single-structure quantum dot, a core material of the core-shell quantum dot, and a shell material of the core-shell quantum dot are respectively selected from, but not limited to, at least one of a vII-VI compound, a group IV-VI compound, a group III-V compound, and a group I-III-VI compound.

The group II-VI compound is selected from, but not limited to, at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe.

The group IV-VI compound is selected from, but not limited to, at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe.

The group III-V compound is selected from, but not limited to, at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb.

The group I-III-VI compound is selected from, but not limited to, at least one of CuInS₂, CuInSe₂ and AgInS₂.

As an example, the core-shell structured quantum dot could be selected from CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS and InP/ZnSe/ZnS.

The perovskite semiconductor material is selected from, but not limited to, a doped or undoped inorganic perovskite semiconductor, or an organic-inorganic hybrid perovskite semiconductor.

The inorganic perovskite semiconductor has a general structure formula of AMX₃, wherein A is a Cs⁺ ion, M is a divalent metal cation selected from at least one of Pb²⁺, Sn², Cu²⁺, Ni²⁺, Cd²⁺, Cr²⁺, Mn²⁺, Co²⁺, Fe²⁺, Ge²⁺, Yb²⁺ and Eu²⁺, and X is a halide anion selected from at least one of Cl⁻, Br⁻ and I⁻.

The organic-inorganic hybrid perovskite semiconductor has a general structure formula of BMX₃, wherein B is an organic amine cation selected from CH₃(CH₂)ₙ₋₂NH³⁺ or [NH₃(CH₂)ₙNH₃]²⁺ (wherein n≥2), M is a divalent metal cation selected from at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halide anion selected from at least one of Cl⁻, Br⁻ and I⁻.

The film in the present disclosure could improve the flexibility and deformation resistance of the emission material layer when used in the emission material layer of the photoelectric device, reduces the phenomenon of film cracking and internal structure damage of the photoelectric device when repeatedly bent, and thus enables the photoelectric device to be used in a flexible display device. In addition, the cross-linked system itself also has high conductivity, and does not reduce the conductivity of the emission material layer after being added into the emission material layer, and could ensure the luminous performance of the photoelectric device.

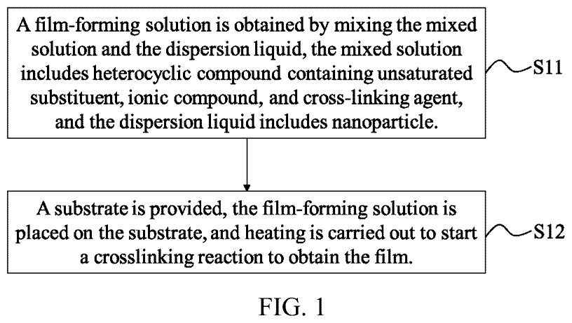

Referring to FIG. 1, the present disclosure further provides a preparation method of the film which includes step S11-S12.

In step S11, a film-forming solution is obtained by mixing the mixed solution and the dispersion liquid, the mixed solution includes heterocyclic compound containing unsaturated substituent, ionic compound, and cross-linking agent, and the dispersion liquid includes nanoparticle.

In step S12, a substrate is provided, the film-forming solution is placed on the substrate, and heating is carried out to start a crosslinking reaction to obtain the film.

In some embodiments, the heterocyclic compound is selected from at least one of pyrazole and pyridine. The unsaturated substituent is selected from vinyl or propenyl.

In some embodiments, the ionic compound contains an imidazole cation as the cation and a halide anion as the anion, so that the finally formed cross-linked system could be referred to as a cross-linked ionic liquid, and the cross-linked ionic liquid has good conductivity.

In some embodiments, the cross-linking agent is selected from at least one of divinylbenzene and N,N′-methylenebisacrylamide.

The structural formula A3-1 of the divinylbenzene is as follows:

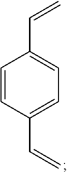

A3-1. A3-1 corresponds to the production of

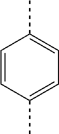

in formula I.

The structural formula A₃-2 of the N,N′-methylenebisacrylamide is as follows:

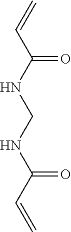

A3-2. A3-2 corresponds to the production of

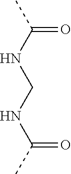

in formula I.

In some embodiments, the mixed solution further includes a solvent. The solvent is a substance that has certain volatility at room temperature or when heated and does not react with the heterocyclic compound containing unsaturated substituent, the ionic compound and the cross-linking agent. Specifically, the solvent could be selected from at least one of ethanol, methanol, propanol, n-octane and the like. It could be understood that ethanol, methanol, propanol and n-octane are only part of the enumeration of the solvent, and the solvent is not limited to one of ethanol, methanol, propanol, n-octane and the like.

In some embodiments, the mixed solution is prepared by the following method: the heterocyclic compound containing unsaturated substituent is dispersed in a solvent, then the ionic compound is added and mixed, and finally the crosslinking agent is added and mixed to obtain the mixed solution.

In some embodiments, a temperature of the heating could be 75-90° C., or 78° C., 79° C., 80° C., 82° C., 84° C., 85° C., 87° C., 89° C. and the like, or a range formed by any two of the above values.

In some embodiments, a time of the heating could be 10-20 min, or 12 min, 15 min, 16 min, 18 min, 19 min and the like, or a range formed by any two of the above values.

In some embodiments, a molar ratio of the heterocyclic compound containing unsaturated substituent, the ionic compound and the cross-linking agent is (0-3):(2-3):(1-2). When the molar number of the heterocyclic compound containing unsaturated substituent is 0 mol, the heterocyclic compound containing unsaturated substituent could not be added in step S11. At this time, the mixed solution is prepared by the following method: the ionic compound is dispersed in a solvent, then the crosslinking agent is added and mixed to obtain the mixed solution.

In some embodiments, the molar ratio of the heterocyclic compound containing unsaturated substituent, the ionic compound and the cross-linking agent could be (2-3):(2-3):(1-2).

In some embodiments, a concentration of the heterocyclic compound containing unsaturated substituent could be 0-0.3 mol/L, or 0.2-0.3 mol/L.

In some embodiments, a concentration of the ionic compound could be 0.2-0.3 mol/L.

In some embodiments, a concentration of the cross-linking agent could be 0.1-0.2 mol/L.

In some embodiments, the cross-linked system could be cross-linked by the ionic compound and the cross-linking agent, or cross-linked by the heterocyclic compound containing unsaturated substituent, the ionic compound and the cross-linking agent.

The heterocyclic compound containing an unsaturated substituent is selected from at least one of 4-halogen-1-vinylpyrazole and 4-halogen-1-vinylpyridine. The 4-halogen-1-vinylpyridine could be selected from at least one of 4-chloro-1-vinylpyridine and 4-bromo-1-vinylpyridine. The 4-halogen-1-vinylpyrazole could be selected from at least one of 4-chloro-1-vinylpyrazole and 4-bromo-1-vinylpyrazole.

A structural formula A2-1 of the 4-halogen-1-vinylpyrazole is as follows:

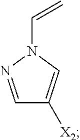

A2-1. The A2-1 corresponds to the production of

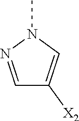

in formula I. The X₂ is selected from any one of Cl, Br or I. Exemplarily, the 4-halogen-1-vinylpyrazole is selected from any one or several of 4-chloro-1-vinylpyrazole and 4-bromo-1-vinylpyrazole.

A structural formula A2-2 of the 4-halogen-1-vinylpyridine is as follows:

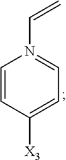

A2-2. The A2-2 corresponds to the production of

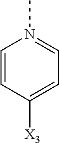

X₃ in formula I. The X₃ is selected from any one of Cl, Br or I. Exemplarily, the 4-halogen-1-vinylpyridine is selected from any one or several of 4-chloro-1-vinylpyridine and 4-bromo-1-vinylpyridine.

The ionic compound could be a 1-vinyl-3-alkyl imidazole halide salt. Further, the 1-vinyl-3-alkyl imidazole halide salt is selected from at least one of 1-vinyl-3-ethyl imidazole chloride, 1-vinyl-3-ethyl imidazole bromide, 1-vinyl-3-propyl imidazole chloride, 1-vinyl-3-propyl imidazole bromide, 1-vinyl-3-butyl imidazole chloride, and 1-vinyl-3-butyl imidazole bromide.

A structural formula A1 of the 1-vinyl-3-alkyl imidazole halide salt is as follows:

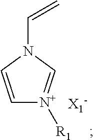

A₁. The R₁ is selected from an alkyl group having 1-6 carbon atoms. X₁⁻ represents any one of Cl⁻, Br⁻, or I⁻. Exemplarily, the 1-vinyl-3-alkyl imidazole halide salt is selected from any one or several of 1-vinyl-3-ethyl imidazole chloride, 1-vinyl-3-ethyl imidazole bromide, 1-vinyl-3-propyl imidazole chloride, 1-vinyl-3-propyl imidazole bromide, 1-vinyl-3-butyl imidazole chloride, and 1-vinyl-3-butyl imidazole bromide.

Alternatively, in the embodiment of the present disclosure, a thickness of the film obtained by the above preparation method is 30 nm to 40 nm.

The whole cross-linked system of the embodiment of the present disclosure has good transparency and does not affect the luminous performance of the nanoparticle, and therefore, the photoelectric device of the present disclosure could be used in a flexible display device. In addition, the cross-linked system contains cations and anions, and therefore, has high conductivity itself, does not reduce the conductivity of the film after the cross-linked system is formed in the film, and could ensure the luminous performance of the photoelectric device.

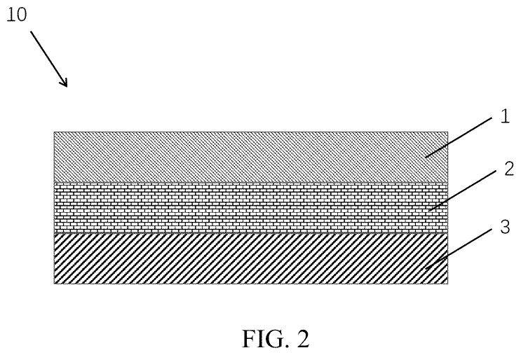

The present disclosure also provides a photoelectric device. Referring to FIG. 2, FIG. 2 is a schematic diagram of the structure of a photoelectric device according to an embodiment of the present disclosure. The photoelectric device 10 in FIG. 2 includes an anode 1, a cathode 3, and an emission material layer 2, located between the anode 1 and the cathode 3.

In some embodiments, the emission material layer 2 includes the film (or quantum dot luminous film) in any of the above embodiments. In some other embodiments, the emission material layer 2 consists of the film in any of the above embodiments.

It could be understood that the emission material layer 2 could only include a single layer of film, or could include two or more layers of film sublayers, as long as a thickness of the emission material layer 2 is ensured to be within 30 nm to 40 nm. The thickness of the emission material layer could be 31 nm, 32 nm, 33 nm, 34 nm, 35 nm, 36 nm, 37 nm, 38 nm, 39 nm or a range formed by any two of the values.

The anode 1 and the cathode 3 are independently selected from a metal electrode, a carbon electrode, a doped or undoped metal oxide electrode and a composite electrode.

A material of the metal electrode is selected from at least one of Al, Ag, Cu, Mo, Au, Ba, Ca and Mg. A material of the carbon electrode is selected from at least one of graphite, carbon nanotube, graphene and carbon fiber. A material of the doped or undoped metal oxide electrode is selected from at least one of ITO, FTO, ATO, AZO, GZO, IZO, MZO and AMO. A material of the composite electrode is selected from at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS. Herein, “/” represents a stacked structure, for example, the composite electrode AZO/Ag/AZO represents an electrode with a composite structure of three layers of AZO layer, Ag layer and AZO layer stacked. A thickness of the anode 1 could be 50-110 nm, such as 50-60 nm, 60-70 nm, 70-80 nm, 80-90 nm, 90-100 nm, 100-110 nm, etc., or a range formed by any two of the values. A thickness of the cathode 3 could be 30-100 nm, such as 30-40 nm, 40-50 nm, 50-60 nm, 60-70 nm, 70-80 nm, 80-90 nm, etc., or a range formed by any two of the values.

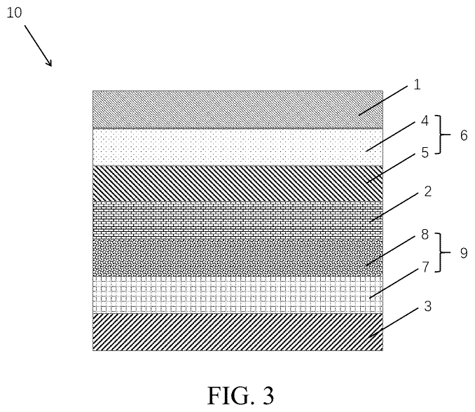

In some other embodiments, referring to FIG. 3, the photoelectric device 10 further includes a hole functional layer 6 between the anode 1 and the emission material layer 2 in addition to the structure in FIG. 2. The hole functional layer 6 includes one or more of a hole injection layer 4 and a hole transport layer 5. When the hole functional layer 6 includes both the hole injection layer 4 and the hole transport layer 5, the hole injection layer 4 is arranged on the side close to the anode 1, and the hole transport layer 5 is arranged on the side close to the emission material layer 2.

A material of the hole injection layer 4 is a material having hole injection capability. The material of the hole injection layer 4 could be selected from one or more of poly(3,4-ethylenedioxythiophene)-polystyrenesulfonic acid (PEDOT:PSS), 2,3,5,6-tetrafluoro-7,7′,8,8′-tetracyanoquinodimethane (F4-TCNQ), 2,3,6,7,10,11-hexacyano-1,4,5,8,9,12-hexaazatriphenylene (HATCN), copper phthalocyanine (CuPc), MCC, transition metal oxide, transition metal chalcogenide; wherein the transition metal oxide includes one or more of NiO, MoO₂, WO₃, CuO; the transition metal chalcogenide includes one or more of MoS₂, MoSe₂, WS₃, WSe₃, CuS. A thickness of the hole injection layer 4 could be 15-45 nm, such as 15-20 nm, 20-25 nm, 25-30 nm, 30-40 nm, etc., or a range formed by any two of the values.

A material of the hole transport layer 5 is a material having hole transport capability. The material of the hole transport layer 5 could be selected from one or more of poly(9,9-dioctylfluorene-CO—N-(4-butylphenyl)diphenylamine) (TFB), polyvinylcarbazole (PVK), poly(N,N′-bis(4-butylphenyl)-N,N′-bis(phenyl)benzidine) (poly-TPD), poly(9,9-dioctylfluorene-co-bis-N,N-phenyl-1,4-phenylenediamine) (PFB), 4,4′,4″-tris(carbazol-9-yl)triphenylamine (TCATA), 4,4′-bis(9-carbazolyl)biphenyl (CBP), N,N′-diphenyl-N,N′-di(3-methylphenyl)-1,1′-biphenyl-4,4′-diamine (TPD), N,N′-diphenyl-N,N′-(1-naphthyl)-1,1′-biphenyl-4,4′-diamine (NPB), poly(3,4-ethylenedioxythiophene)-poly(styrenesulfonic acid) (PEDOT:PSS), TPH, TAPC (cas: 58473-78-2), Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, CuSCN. A thickness of the hole transport layer 52 could be 20-50 nm, such as 20-25 nm, 25-30 nm, 30-35 nm, 35-40 nm, 40-45 nm, etc., or a range formed by any two of the values.

In some other embodiments, referring to FIG. 3, the photoelectric device 10 further includes an electron functional layer 9 between the emission material layer 2 and the cathode 3 in addition to the structure of FIG. 2. The electron functional layer 9 includes one or more of an electron injection layer 7 and an electron transport layer 8. When the electron functional layer 9 includes both the electron injection layer 7 and the electron transport layer 8, the electron injection layer 7 is arranged on the side of the cathode 3, and the electron transport layer 8 is arranged on the side of the emission material layer 2.

A material of the electron transport layer 8 includes one or more of inorganic nanocrystalline material, doped inorganic nanocrystalline material, and organic material. The inorganic nanocrystalline material includes one or more of zinc oxide, titanium dioxide, tin dioxide, aluminum oxide, calcium oxide, silicon dioxide, gallium oxide, zirconium oxide, nickel oxide, and zirconia. The doped inorganic nanocrystalline material is inorganic nanocrystalline material containing a doping element, and the doping element is selected from one or more of Mg, Ca, Li, Ga, Al, Co, and Mn. The organic material includes one or both of polymethyl methacrylate and polyvinyl butyral. A thickness of the electron transport layer could be 20-50 nm, such as 20-30 nm, 35-40 nm, 42-49 nm, etc., or a range formed by any two of the values.

A material of the electron injection layer 7 includes at least one of LiF/Yb, RbBr, ZnO, Ga₂O₃, Cs₂CO₃, and Rb₂CO₃. A thickness of the electron injection layer could be 15-30 nm, such as 20-25 nm, etc.

It could be understood that the photoelectric device 10 could further include some functional layers for the photoelectric device, such as an electron blocking layer and a hole blocking layer, etc., in addition to the functional layers described above.

It could be understood that the materials and thicknesses of the layers of the photoelectric device 10 could be set and adjusted according to the luminous requirements of the photoelectric device 10.

The photoelectric device 10 further includes a substrate (not shown in figure). The substrate could be a rigid substrate or a flexible substrate. The rigid substrate could be ceramic materials or various glass materials, etc. A material of the flexible substrate could be a substrate formed of polyimide film (PI) and derivatives thereof, polyethylene naphthalate (PEN), phosphoenolpyruvic acid (PEP), or diphenylene ether resin, etc.

It could be understood that the photoelectric device 10 could be an upright photoelectric device or an inverted photoelectric device. When the photoelectric device 10 is an upright photoelectric device, the substrate is bonded to the side of the anode 1 away from the emission material layer 2. When the photoelectric device 10 is an inverted photoelectric device, the substrate is bonded to the side of the cathode 3 away from the emission material layer 2.

Accordingly, the present disclosure provides a method for preparing a photoelectric device which includes following steps.

A cathode is provided.

An emission material layer is formed on the surface of the cathode.

An anode is formed on the emission material layer.

In some embodiments, the emission material layer includes the film in the above embodiments, or consists of the film in the above embodiments, or is prepared by the preparation method of the film in the above embodiments.

The present disclosure provides another preparation method of a photoelectric device, which includes the following steps.

An anode is provided.

An emission material layer is formed on the surface of the anode.

A cathode is formed on the emission material layer.

In some embodiments, the emission material layer includes the film in the above embodiments, or consists of the film in the above embodiments, or is prepared by the preparation method of the film in the above embodiments.

In the preparation method, before or after the emission material layer is formed, a hole functional layer is further formed. The hole functional layer includes one or more of a hole injection layer and a hole transport layer. When the hole functional layer includes the hole injection layer and the hole transport layer, the hole injection layer is arranged on the side close to the anode, and the hole transport layer is arranged on the side close to the emission material layer.

In the preparation method, before or after the emission material layer is formed, an electron functional layer is further formed. The electron functional layer includes one or more of an electron injection layer and an electron transport layer. When the electron functional layer includes the electron transport layer and the electron injection layer, the electron injection layer is arranged on the side close to the cathode, and the electron transport layer is arranged on the side close to the emission material layer.

Specifically, a method for forming above functional layers could be a chemical method or a physical method. The functional layers include but are not limited to the cathode, the emission material layer, the cathode, the hole functional layer, and the electron functional layer. The chemical method includes chemical vapor deposition, successive ion layer adsorption and reaction, anodic oxidation, electrolytic deposition, and co-precipitation. The physical method includes physical coating and a solution method. The physical coating includes thermal evaporation coating, electron beam evaporation coating, magnetron sputtering, multi-arc ion coating, physical vapor deposition, atomic layer deposition, pulsed laser deposition, and the like. The solution method could be spin coating, printing, inkjet printing, blade coating, printing, dip coating, immersion, spraying, rolling, casting, slot coating, stripe coating, and the like.

The present disclosure further provides a display device, which includes the film in any of the above embodiments, or includes the film prepared by the preparation method of the film in the above embodiments, or includes the photoelectric device in any of the above embodiments, or is prepared by the preparation method of the photoelectric device in any of the above embodiments. The display device could be an electronic product with a display function, and the electronic product includes but is not limited to a smart phone, a tablet computer, a notebook computer, a digital camera, a digital video camera, a smart wearable device, a smart weighing electronic scale, a vehicle-mounted display, a television, or an electronic book reader. The smart wearable device could be a smart bracelet, a smart watch, a virtual reality (VR) helmet, or the like.

The present disclosure is specifically described below by means of specific examples. The following examples are only part of the examples of the present disclosure and do not constitute a limitation of the present disclosure. The related properties of the emission material layers and the photoelectric devices of the following examples and comparative examples are tested by the following methods, and the test results are shown in Table 1.

1. Flexibility test of the photoelectric device. The flexibility data are mainly determined by the curvature of the device that could be bent, for example, the curvature 4000R refers to the degree of bending of a circle with a radius of 4 m, and the other data are the same. In general, the smaller the radius of curvature, the better the flexibility and the better the deformation resistance.

2. Conductivity test of the photoelectric device. The conductivity is generally tested by the conductivity of the whole device, for example, the conductivity of the examples of the present disclosure is evaluated by measuring the current (mA) of the device under 6 V voltage. The higher the current, the higher the conductivity value, indicating the stronger the conductivity.

### Film Example 1

The film example provides a preparation method of a film, which includes step S1-S3.

In step S1, 4-chloro-1-vinylpyrazole (belonging to a heterocyclic compound containing an unsaturated substituent), 1-vinyl-3-ethylimidazole bromide (belonging to an ionic compound), a crosslinking agent (divinylbenzene) and a solvent (n-octane) are mixed to obtain a 1 L mixed solution; a concentration of the 4-chloro-1-vinylpyrazole is 0.2 mol/L, a concentration of the 1-vinyl-3-ethylimidazole bromide is 0.2 mol/L, and a concentration of the divinylbenzene is 0.1 mol/L.

In step S2, quantum dot is dispersed in a solvent (n-octane) to obtain a dispersion liquid, and the dispersion liquid is mixed with the 1 L mixed solution to obtain a film-forming liquid. The quantum dot is CdZnSe, a ligand of the quantum dot is oleic acid, and a particle size of the quantum dot is 15 nm. In the film-forming liquid, a mass ratio of the solute in the mixed solution to the quantum dot is 1:100.

In step S3, a substrate is provided, the film-forming liquid is disposed on the substrate, heating is performed to 80° C. and lasts for 10 min to start a crosslinking reaction, and a film is obtained after the crosslinking reaction is completed. In the film, the 4-chloro-1-vinylpyrazole, the 1-vinyl-3-ethylimidazole bromide and the crosslinking agent are crosslinked to form a cross-linked system with voids, and the quantum dot is filled in the voids of the cross-linked system.

In the film of the film example 1, a thickness of the film is 30 nm. The current passing through the film under 6 V voltage is 5.1 mA, a transparency parameter of the film is 91%, a LUMO energy level of the film is 3.5-3.6 eV, and a HOMO energy level of the film is 6.0-6.2 eV.

### Film Example 2

The film example provides a preparation method of a film, which includes step S1-S3.

In step S1, 4-chloro-1-vinylpyrazole and 4-chloro-1-vinylpyridine (belonging to a heterocyclic compound containing an unsaturated substituent), 1-vinyl-3-ethylimidazole bromide (belonging to an ionic compound), a crosslinking agent (divinylbenzene) and a solvent (n-octane) are mixed to obtain a 1 L mixed solution; a concentration of the 4-chloro-1-vinylpyrazole is 0.15 mol/L, a concentration of the 4-chloro-1-vinylpyridine is 0.15 mol/L, a concentration of the 1-vinyl-3-ethylimidazole bromide is 0.3 mol/L, and a concentration of the divinylbenzene is 0.2 mol/L.

In step S2, quantum dot is dispersed in a solvent (n-octane) to obtain a dispersion liquid, and the dispersion liquid is mixed with the 1 L mixed solution to obtain a film-forming liquid. The quantum dot is CdTe, a ligand of the quantum dot is oleic acid, and a particle size of the quantum dot is 20 nm. In the film-forming liquid, a mass ratio of the solute in the mixed solution to the quantum dot is 1:20.

In step S3, a substrate is provided, the film-forming liquid is disposed on the substrate, heating is performed to 90° C. and lasts for 14 min to start a crosslinking reaction, and a film is obtained after the crosslinking reaction is completed. In the film, the 4-chloro-1-vinylpyrazole, the 4-chloro-1-vinylpyridine, the 1-vinyl-3-ethylimidazole bromide and the crosslinking agent are crosslinked to form a cross-linked system with voids, and the quantum dot is filled in the voids of the cross-linked system.

In the film of Film Example 1, a thickness of the film is 40 nm. The current passing through the film under 6 V voltage is 5.3 mA, a transparency parameter of the film is 89%, a LUMO energy level of the film is 3.5-3.6 eV, and a HOMO energy level of the film is 6.0-6.2 eV.

### Film Comparative Example 1

The film comparative example does not use the heterocyclic compound containing unsaturated substituent, the ionic compound and the cross-linking agent in the above film examples to form a cross-linked system, but uses other cross-linking materials to form a cross-linked system. The method for preparing the film of the film comparative example, which includes step S1-S3.

In step S1, 25 g of polyacrylamide was weighed into a beaker, 5 mL of methanol was added, and then deionized water was added to 50 mL, and stirred until completely dissolved to obtain a polyacrylamide solution.

In step S2, citric acid and aluminum chloride were dissolved in deionized water at a molar ratio of 1:2, and the pH value was adjusted to 7 to obtain a cross-linking agent aluminum citrate solution.

In step S3, quantum dot was dispersed in a solvent (n-octane) to obtain a dispersion liquid. The dispersion liquid was mixed with the polyacrylamide solution and the cross-linking agent aluminum citrate solution, heated in a constant-temperature water bath at 60° C., taken out after gelation, coated on a substrate, and dried to obtain a film.

After testing, a thickness of the film is 120 nm. The film has very low conductivity and poor bending resistance, is easy to break, and is difficult to meet the performance of high conductivity and bending resistance, and is therefore difficult to be used as an emission material layer of a flexible photoelectric device.

### Film Comparative Example 2

The film comparative example provides a method for preparing a film, which includes step S1-S2.

In step S1, quantum dot was dispersed in a solvent (n-octane) to obtain a dispersion liquid. The quantum dot was CdZnSe, a ligand of the quantum dot was oleic acid, and a particle size of the quantum dot was 15 nm. In the dispersion liquid, an added mass of the quantum dot was equal to the added mass of the quantum dot in Film Example 1.

In step S2, a substrate was provided, the dispersion liquid was spin-coated on the substrate by a spin coating method, and after the spin coating process was completed, the substrate was placed on a heating table at 80° C. for heating for 10 min to obtain a film with a thickness of 30 nm.

In the film comparative example, a thickness of the film was 30 nm. A current passing through the film under a voltage of 6 V was 5.2 mA, a LUMO energy level of the film was 3.5-3.6 eV, and a HOMO energy level of the film was 6.0-6.2 eV.

According to a comparison of the results of Film Example 1 and the respective film comparative examples, the conductivity of the film containing the cross-linked system of the present disclosure is slightly lower than that of the film without the cross-linked system, but is still higher than that of the film containing other cross-linked systems (such as the cross-linked system of Film Comparative Example 1). In addition, the presence or absence of the cross-linked system of the present disclosure does not affect the LUMO energy level and the HOMO energy level of the film, indicating that the film of the present disclosure could be used in the emission material layer of a photoelectric device.

### Film Comparative Example 3

The film comparative example provides a method for preparing a film, which includes step S1-S2.

In step S1, quantum dot was dispersed in a solvent (n-octane) to obtain a dispersion liquid. The quantum dot was CdTe, a ligand of the quantum dot was oleic acid, and a particle size of the quantum dot was 20 nm. In the dispersion liquid, an added mass of the quantum dot was equal to the added mass of the quantum dot in Film Example 2.

In step S2, a substrate was provided, the dispersion liquid was spin-coated on the substrate by a spin coating method, and after the spin coating process was completed, the substrate was placed on a heating table at 90° C. for heating for 14 min to obtain a film with a thickness of 40 nm.

In the film comparative example, a thickness of the film was 40 nm. A current passing through the film under a voltage of 6 V was 5.4 mA, a LUMO energy level of the film was 3.5-3.6 eV, and a HOMO energy level of the film was 6.0-6.2 eV.

According to a comparison of the results of Film Example 2 and the respective film comparative examples, the conductivity of the film containing the cross-linked system of the present disclosure is slightly lower than that of the film without the cross-linked system, but is still higher than that of the film containing other cross-linked systems (such as the cross-linked system of Film Comparative Example 1). In addition, the presence or absence of the cross-linked system of the present disclosure does not affect the LUMO energy level and the HOMO energy level of the film, indicating that the film of the present disclosure could be used in the emission material layer of a photoelectric device.

### Device Example 1

The device example provides a photoelectric device (i.e. a quantum dot luminous diode) and a preparation method thereof which includes step S1-S6.

In step S1, in a spin coating device, a hole injection layer with a thickness of 20 nm was formed on an ITO layer (a thickness of the ITO layer was 80 nm) by a spin coating method, and a material of the hole injection layer was PEDOT:PSS.

In step S2, in inert atmosphere, TFB was spin-coated on the hole injection layer to obtain a hole transport layer with a thickness of 25 nm.

In step S3, quantum dot luminescent spin-coating liquid was spin-coated on the hole transport layer, and then it was placed on a heating table at 80° C. for 10 min to carry out cross-linking reaction. After the cross-linking reaction, a luminescent layer with a thickness of 35 nm was obtained. The quantum dot luminous spin-coating liquid includes 4-chloro-1-vinylpyrazole, 1-vinyl-3-ethylimidazole bromide, a cross-linking agent (divinylbenzene), quantum dot, and a solvent (n-octane). The quantum dot is CdZnSe, and a ligand of the quantum dot is oleic acid. In the cross-linking reaction process, the 4-chloro-1-vinylpyrazole monomer, the 1-vinyl-3-ethylimidazole bromide monomer, and the cross-linking agent undergo cross-linking polymerization reaction, and unpolymerized monomer is removed in the spin-coating process, to finally obtain a cross-linked system wrapping the quantum dot. In the cross-linking reaction process, the 4-chloro-1-vinylpyrazole, the 1-vinyl-3-ethylimidazole bromide, and the cross-linking agent do not undergo cross-linking with the ligand (oleic acid) of the quantum dot. After the cross-linked system is formed, the voids in the cross-linked system are filled with the quantum dot, and the cross-linked system prevents the movement of the quantum dot through physical limitation. When the emission material layer is finally formed, a mass ratio of the quantum dot to the cross-linked system is 1:50.

In step S4, ZnO nanoparticles were spin-coated on the luminescent layer to form an electron transport layer with a thickness of 30 nm.

In step S5, Ag was evaporated on the electron transport layer by vacuum evaporation, and a cathode with a thickness of 80 nm was obtained.

In step S6, UV-curing glue packaging is carried out to obtain the quantum dot luminous diode.

The structure of the quantum dot luminous diode in the device embodiment is anode/hole injection layer/hole transport layer/emission material layer/electron transport layer/cathode. A HOMO energy level of the emission material layer is 6.2 eV, and a HOMO energy level of the hole transport layer is 5.8 eV.

### Device Embodiment 2 to Device Embodiment 5, Device Comparative Example 1 to Device Comparative Example 3

The device embodiments and the device comparative examples differ from Device Embodiment 1 only in that a mass ratio of the cross-linked system formed after cross-linking to the quantum dot is different from that of Device Embodiment 1 by controlling the ratio of the added monomer. Specifically, in Device Embodiment 1, a mass ratio of the cross-linked system to the quantum dot in the emission material layer is 1:50. In Device Embodiment 2, a mass ratio of the cross-linked system to the quantum dot in the emission material layer is 1:10. In Device Embodiment 3, a mass ratio of the cross-linked system to the quantum dot in the emission material layer is 1:30. In Device Embodiment 4, a mass ratio of the cross-linked system to the quantum dot in the emission material layer is 1:80. In Device Embodiment 5, a mass ratio of the cross-linked system to the quantum dot in the emission material layer is 1:100. The emission material layer of Device Embodiment 5 could refer to the preparation method and materials of the film provided in Film Embodiment 1.

In the device comparative example 1, a mass ratio of the cross-linked system to the quantum dot in the emission material layer is 1:3, which is not within the range of 1:(10-100). In the device comparative example 2, a mass ratio of the cross-linked system to the quantum dot in the emission material layer is 1:150, which is also not within the range of 1:(10-100). In the device comparative example 3, when the emission material layer is formed by using the spin coating method, the quantum dot luminous spin coating liquid contains only the quantum dot, and does not contain the 4-chloro-1-vinylpyrazole, 1-vinyl-3-ethylimidazole bromide, and the cross-linking agent (divinylbenzene), and therefore, the cross-linked system does not exist in the emission material layer.

According to the test data of the device examples and the device comparative examples in Table 1, if a mass ratio of the cross-linked system to the quantum dot in the finally generated emission material layer is too small, the obtained photoelectric device has poor flexibility, poor bending resistance, and poor conductivity, thereby affecting the luminous effect of the emission material layer. If a mass ratio of the cross-linked system to the quantum dot in the finally generated emission material layer is too large, the flexibility is too large, which is not conducive to repeated bending, and the luminous effect of the emission material layer is also affected.

### Device Example 6 to Device Example 10

The device examples are different from the device example 1 only in that the types of the cross-linking monomer are different. The cross-linking monomer of the device example 1 include 4-chloro-1-vinylpyrazole monomer and 1-vinyl-3-ethylimidazole bromide monomer. The device example 6 replaces the “4-chloro-1-vinylpyrazole monomer” in the device example 1 with “4-chloro-1-vinylpyridine monomer” (the types of the cross-linking monomer are changed), and the rest remains unchanged. The device example 7 replaces the “4-chloro-1-vinylpyrazole monomer” in the device example 1 with “4-bromo-1-vinylpyrazole monomer” (the types of the substituents are changed), and the rest remains unchanged. The device example 8 replaces the “1-vinyl-3-ethylimidazole bromide monomer” in the device example 1 with “1-vinyl-3-ethylimidazole chloride monomer” (the types of the substituents are changed), and the rest remains unchanged. The device example 9 replaces the “1-vinyl-3-ethylimidazole bromide monomer” in the device example 1 with “1-vinyl-3-propylimidazole chloride monomer” (the length of the side chain alkyl group is increased and the types of the substituents are changed), and the rest remains unchanged. The device example 10 replaces the “1-vinyl-3-ethylimidazole bromide monomer” in the device example 1 with “1-vinyl-3-butylimidazole chloride monomer” (the length of the side chain alkyl group is increased and the types of the substituents are changed), and the rest remains unchanged.

As can be seen from the test data of each device example in the table, the above replacement of the cross-linking monomer of each device example could play a similar role. Both the pyridine and pyrazole cross-linking monomer could form a suitable energy level gradient between the emission material layer and the hole transport layer (HTL), thereby reducing the injection barrier between the emission material layer and the hole transport layer (HTL), and could also shorten the distance between the quantum dot and the HTL molecules, because insulating quantum dot ligand could cause the distance between the quantum dot and the HTL molecules to be too large. In addition, the 1-vinyl-3-alkyl imidazole chloride salt has a greater promoting effect on the hole transport of the quantum dot than the 1-vinyl-3-alkyl imidazole bromide salt when present in the emission material layer. However, if the length of the side chain alkyl group is increased, the conductivity will decrease, but as long as the number of carbon atoms of the side chain alkyl group is in the range of 1 to 6, the required device performance could be achieved.

### Device Example 11 to Device Example 15

Device Example 11 differs from Device Example 1 only in that the cross-linking agent (divinylbenzene) in Device Example 1 is replaced with N,N′-methylenebisacrylamide. Device Example 12 differs from Device Example 2 only in that the cross-linking agent (divinylbenzene) in Device Example 2 is replaced with N,N′-methylenebisacrylamide. Device Example 13 differs from Device Example 5 only in that the cross-linking agent (divinylbenzene) in Device Example 5 is replaced with N,N′-methylenebisacrylamide. Device Example 14 differs from Device Example 6 only in that the cross-linking agent (divinylbenzene) in Device Example 6 is replaced with N,N′-methylenebisacrylamide. Device Example 15 differs from Device Example 8 only in that the cross-linking agent (divinylbenzene) in Device Example 8 is replaced with N,N′-methylenebisacrylamide.

As can be seen from the test data of each device example in the table, a molecular weight of divinylbenzene is similar to that of N,N′-methylenebisacrylamide, but the activity of divinylbenzene is higher, so the cross-linking performance is slightly better. This shows that the cross-linking agents divinylbenzene and N,N′-methylenebisacrylamide could be mutually substituted.

### Device Example 16 to Device Example 17, Device Comparative Example 4 and Device Comparative Example 5

The device examples differ from device example 1 only in that a thickness of the emission material layer is changed by controlling the number of spin coating. A thickness of the emission material layer in device example 1 is 35 nm. A thickness of the emission material layer in device example 16 is 30 nm. A thickness of the emission material layer in device example 17 is 40 nm. A thickness of the emission material layer in device comparative example 4 is 15 nm, which is less than the thickness of the emission material layer in device example 1. A thickness of the emission material layer in device comparative example 5 is 70 nm, which is greater than the thickness of the emission material layer in device example 1. According to the test results, if the thickness of the emission material layer is too thin, the luminous substance is too little, and the luminous efficiency of the photoelectric device is greatly affected, which could not meet the luminous requirements. If the thickness of the emission material layer is too thick, the light extraction efficiency of the emission material layer is too low, the light extraction rate is too poor, and the luminous performance of the photoelectric device is also affected.

### Device Examples 18 to Device Example 20

The device examples differ from device example 1 only in that the types of quantum dot and ligand are changed. A composition of the quantum dot in device example 18 is CdZnSe, and a ligand is oleic acid. A composition of the quantum dot in device example 19 is CdSeS, and a ligand is oleylamine. A composition of the quantum dot in device example 20 is CdZnSe/CdTe, and a ligand is 1-octadecene.

In addition, according to the results of the device examples and the device comparative examples, the cross-linked system formed by crosslinking the crosslinking monomer and the crosslinking agent makes the emission material layer have a certain degree of crosslinking, increases the flexibility of the emission material layer, and also has high conductivity because the cross-linked system itself contains a large number of cations and anions. In addition, the pyridine group in the 4-halogen-1-vinyl pyridine monomer or the pyrazole group in the 4-halogen-1-vinyl pyrazole monomer could form a suitable energy level gradient (i.e., the energy level difference between the emission material layer and the HTL) between the emission material layer and the hole transport layer (HTL), reduce the injection barrier between the hole transport layer and the quantum dot layer, shorten the distance between the quantum dots in the emission material layer and the hole transport molecules in the hole transport layer caused by the insulating QD ligand (such as oleylamine, oleic acid, 1-octadecene, etc.), and improve the conductivity and the hole transport performance of the whole emission material layer.

In summary, the present disclosure meets the requirements of the flexible QLED display device for bending resistance and deformation stress resistance, especially for the emission material layer of the QLED flexible device. The quantum dot in the emission material layer are filled in the gaps of the cross-linked system to form an overall stress structure, so that the emission material layer has the required flexibility, the bending resistance and deformation resistance of the emission material layer are improved, and the emission material layer has high deformation stability, so that the emission material layer is not cracked and the internal structure is not damaged in the deformation process or repeated bending process, so as to meet the basic requirements of the flexible QLED display device for the deformation performance of the emission material layer. In addition, the general cross-linking substance will reduce the conductivity of the emission material layer after being doped into the quantum dot in the emission material layer, but the emission material layer of the present disclosure contains a cross-linked system with high conductivity, which could realize cross-linking and also ensure that the conductivity of the emission material layer will not be reduced due to the presence of the cross-linking substance, and the performance of the luminous device is ensured.

TABLE 1

| | Radius of | Current at 6 V |
|---|---|---|
| | curvature | (mA) |
| Example 1 | 1000R | 5.3 |
| Example 2 | 1050R | 5.1 |
| Example 3 | 1070R | 5.0 |
| Example 4 | 1100R | 4.9 |
| Example 5 | 1080R | 4.9 |
| Comparative Example 1 | 5000R | 1.8 |
| Comparative Example 2 | 5200R | 6.1 |
| Comparative Example 3 | 5500R | 3.0 |
| Example 6 | 1000R | 5.3 |
| Example 7 | 1100R | 4.9 |
| Example 8 | 1000R | 5.5 |
| Example 9 | 1200R | 5.1 |
| Example 10 | 1200R | 5.1 |
| Example 11 | 950R | 5.5 |
| Example 12 | 1010R | 5.2 |
| Example 13 | 1040R | 5.1 |
| Example 14 | 950R | 5.5 |
| Example 15 | 980R | 5.6 |
| Example 16 | 1000R | 5.5 |
| Example 17 | 1000R | 5.1 |
| Comparative Example 4 | 2000R | 6.1 |
| Comparative Example 5 | 3000R | 1.5 |
| Example 18 | 1030R | 5.4 |
| Example 19 | 1020R | 5.3 |
| Example 20 | 1040R | 5.5 |

Film, preparation method thereof and photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

1. A film, comprising:
a cross-linked system having voids; and
a nanoparticle filled in the voids;
wherein the cross-linked system comprises a cross-linking material having a general structure as shown in formula I: 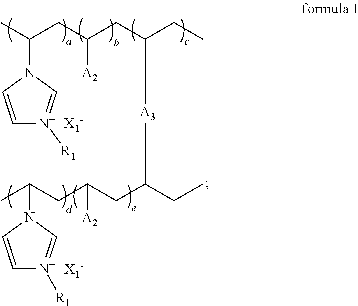
wherein R₁ is selected from an alkyl group having 1-6 carbon atoms;
A₂ is independently selected from any one of 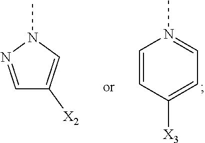
A₃ is selected from any one of 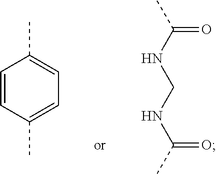
X₁, X₂, X₃ are independently selected from any one of Cl, Br, or I; and
a, c, d are each independently selected from any one of integers from of 2-50, b and e are each independently selected from any one of integers from 0-50.

2. The film according to claim 1, wherein the film is composed of the cross-linked system having voids and the nanoparticle filled in the voids;
a current passing through the film under a voltage of 6 V is 4.9-5.6 mA;
a LUMO energy level of the film is 3.5-3.6 eV; and
a HOMO energy level of the film is 6.0-6.2 eV.

3. The film according to claim 1, wherein a mass ratio of the cross-linked system to the nanoparticle in the film is 1:(10-100);
an average particle size of the nanoparticle is 15-40 nm; and
a thickness of the film is 30-40 nm.

4. The film according to claim 1, wherein the cross-linked system comprises one or more of the following cross-linking compounds having the following general structures: 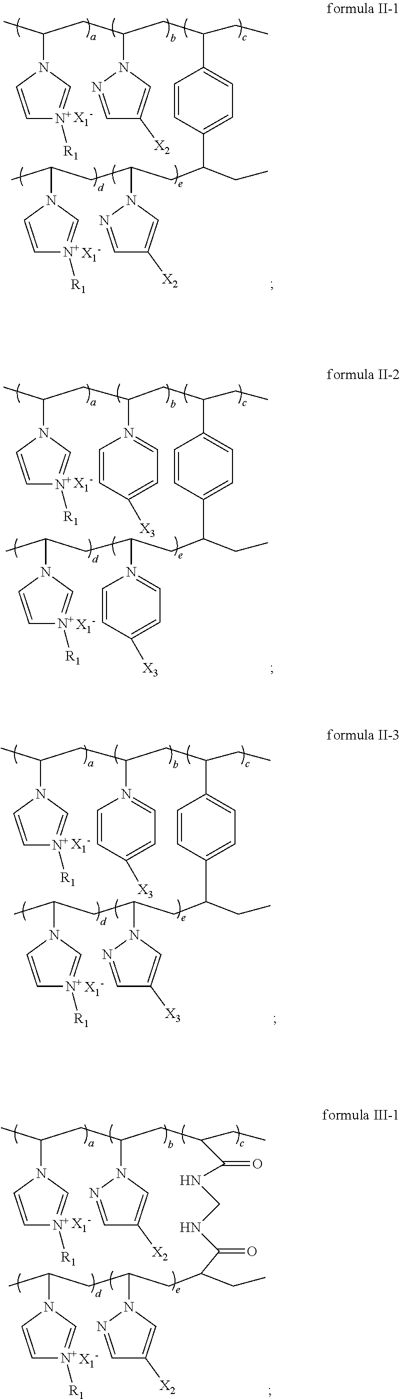 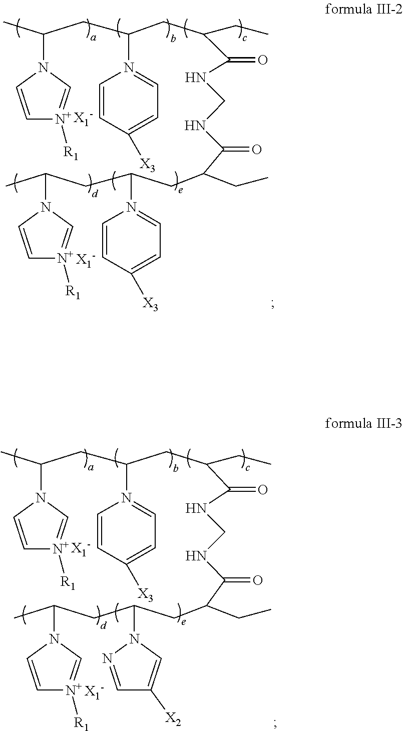
and
b and e are independently selected from any one of integers from 1-50.

5. The film according to claim 1, wherein the nanoparticle comprises quantum dot, and the quantum dot is selected from one or more of a single-structure quantum dot, a core-shell quantum dot, and a perovskite semiconductor material.

6. The film according to claim 5, wherein a material of the single-structure quantum dot, a core material of the core-shell quantum dot, and a shell material of the core-shell quantum dot are respectively selected from a group II-VI compound, a group IV-VI compound, a group III-V compound, and a group I-III-VI compound;
the group II-VI compound is selected from CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe;
the group IV-VI compound is selected from SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe;
the group III-V compound is selected from GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb;
the group I-III-VI compound is selected from CuInS₂, CuInSe₂ and AgInS₂;
the perovskite semiconductor material is selected from a doped or undoped inorganic perovskite semiconductor, or an organic-inorganic hybrid perovskite semiconductor;
the inorganic perovskite semiconductor has a general structure formula of AMX₃, wherein A is a Cs⁺ ion, M is a divalent metal cation selected from at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halide anion selected from at least one of Cl⁻, Br⁻ and I⁻; and
the organic-inorganic hybrid perovskite semiconductor has a general structure formula of BMX₃, wherein B is an organic amine cation selected from CH₃(CH₂)ₙ₋₂NH³⁺ or [NH₃(CH₂)ₙNH₃]²⁺ (wherein n≥2), M is a divalent metal cation selected from at least one of Pb²⁺, Sn²⁺, Cu², Ni²⁺, Cd²⁺, Cr²⁺, Mn²⁺, Co²⁺, Fe²⁺, Ge²⁺, Yb²⁺ and Eu²⁺, and X is a halide anion selected from at least one of Cl⁻, Br⁻ and I⁻.

7. A preparation method of a film, comprising:
providing a mixed solution and a dispersion liquid, the mixed solution comprises heterocyclic compound containing unsaturated substituent, ionic compound, and cross-linking agent, and the dispersion liquid comprises nanoparticle; mixing the mixed solution with the dispersion liquid to obtain a film-forming solution; and
providing a substrate, setting the film-forming solution on the substrate, and heating to start a crosslinking reaction to obtain the film.

8. The preparation method according to claim 7, wherein the heterocyclic compound is selected from at least one of pyrazole and pyridine;
the unsaturated substituent is selected from vinyl or propenyl;
the ionic compound contains an imidazole cation and a halide anion; and
the cross-linking agent is selected from at least one of divinylbenzene and N,N′-methylenebisacrylamide.

9. The preparation method according to claim 7, wherein a temperature of the heating is 75-90° C.; and
a time of the heating is 10-20 min.

10. The preparation method according to claim 7, wherein a molar ratio of the heterocyclic compound containing unsaturated substituent, the ionic compound and the cross-linking agent is (0-3):(2-3):(1-2);
a concentration of the heterocyclic compound containing unsaturated substituent is 0-0.3 mol/L;
a concentration of the ionic compound is 0.2-0.3 mol/L; and
a concentration of the cross-linking agent is 0.1-0.2 mol/L.

11. The preparation method according to claim 10, wherein the molar ratio of the heterocyclic compound containing unsaturated substituent, the ionic compound and the cross-linking agent is (2-3):(2-3):(1-2); and
a concentration of the heterocyclic compound containing unsaturated substituent is 0.2-0.3 mol/L.

12. The preparation method according to claim 7, wherein the heterocyclic compound containing an unsaturated substituent is selected from at least one of 4-halogen-1-vinylpyrazole and 4-halogen-1-vinylpyridine; and
the ionic compound is a 1-vinyl-3-alkyl imidazole halide salt.

13. The preparation method according to claim 12, wherein the 4-halogen-1-vinylpyridine is selected from at least one of 4-chloro-1-vinylpyridine and 4-bromo-1-vinylpyridine;
the 4-halogen-1-vinylpyrazole is selected from at least one of 4-chloro-1-vinylpyrazole and 4-bromo-1-vinylpyrazole; and
the 1-vinyl-3-alkyl imidazole halide salt is selected from at least one of 1-vinyl-3-ethyl imidazole chloride, 1-vinyl-3-ethyl imidazole bromide, 1-vinyl-3-propyl imidazole chloride, 1-vinyl-3-propyl imidazole bromide, 1-vinyl-3-butyl imidazole chloride, and 1-vinyl-3-butyl imidazole bromide.

14. The preparation method according to claim 7, wherein the mixed solution is prepared by the following method: the heterocyclic compound containing unsaturated substituent is dispersed in a solvent, then the ionic compound is added and mixed, and finally the crosslinking agent is added and mixed to obtain the mixed solution.

15. The preparation method according to claim 14, wherein the solvent is selected from at least one of ethanol, methanol, propanol and n-octane.

16. A photoelectric device, comprising:
an anode;
a cathode; and
an emission material layer, located between the anode and the cathode, wherein the emission material layer comprising:
a cross-linked system having voids; and
a nanoparticle filled in the voids;
wherein the cross-linked system comprises a cross-linking material having a general structure as shown in formula I: 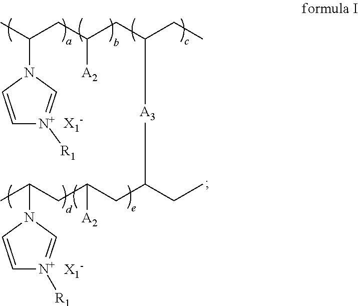
formula I;
wherein R₁ is selected from an alkyl group having 1-6 carbon atoms;
A₂ is independently selected from any one of 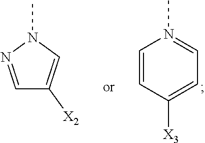
A₃ is selected from any one of 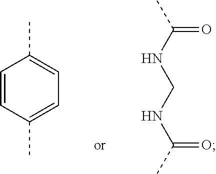
X₁, X₂, X₃ are independently selected from any one of Cl, Br, or I; and
a, c, d are each independently selected from any one of integers from of 2-50, b and e are each independently selected from any one of integers from 0-50.

17. The photoelectric device according to claim 16, wherein a material of the metal electrode is selected from at least one of Al, Ag, Cu, Mo, Au, Ba, Ca and Mg; a material of the carbon electrode is selected from at least one of graphite, carbon nanotube, graphene and carbon fiber; a material of the doped or undoped metal oxide electrode is selected from at least one of ITO, FTO, ATO, AZO, GZO, IZO, MZO and AMO; and a material of the composite electrode is selected from at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS.

18. The photoelectric device according to claim 16, wherein the photoelectric device further comprising: a hole functional layer between the anode and the emission material layer; and
the photoelectric device further comprising: an electron functional layer between the emission material layer and the cathode.

19. The photoelectric device according to claim 18, wherein the hole functional layer comprises one or more of a hole injection layer and a hole transport layer; when the hole functional layer comprises both the hole injection layer and the hole transport layer, the hole injection layer is arranged on the side close to the anode, and the hole transport layer is arranged on the side close to the emission material layer; and
the electron functional layer comprises one or more of an electron injection layer and an electron transport layer; when the electron functional layer comprises both the electron injection layer and the electron transport layer, the electron injection layer is arranged on the side of the cathode, and the electron transport layer is arranged on the side of the emission material layer.

20. The photoelectric device according to claim 19, wherein a material of the hole injection layer is selected from one or more of PEDOT:PSS, F4-TCNQ, HATCN, CuPc, MCC, transition metal oxide, transition metal chalcogenide; wherein the transition metal oxide comprises one or more of NiO, MoO₂, WO₃, CuO; the transition metal chalcogenide comprises one or more of MoS₂, MoSe₂, WS₃, WSe₃, CuS;
a material of the hole transport layer is selected from one or more of TFB, PVK, poly-TPD, PFB, TCATA, CBP, TPD, NPB, PEDOT:PSS, TPH, TAPC, Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, CuSCN;
a material of the electron transport layer comprises one or more of inorganic nanocrystalline material, doped inorganic nanocrystalline material, and organic material; the inorganic nanocrystalline material comprises one or more of zinc oxide, titanium dioxide, tin dioxide, aluminum oxide, calcium oxide, silicon dioxide, gallium oxide, zirconium oxide, nickel oxide, and zirconia; the doped inorganic nanocrystalline material is inorganic nanocrystalline material containing a doping element, and the doping element is selected from one or more of Mg, Ca, Li, Ga, Al, Co, and Mn; and the organic material comprises one or both of polymethyl methacrylate and polyvinyl butyral; and
a material of the electron injection layer includes at least one of LiF/Yb, RbBr, ZnO, Ga₂O₃, Cs₂CO₃, and Rb₂CO₃.
